(19) United States
(12) Patent Application Publication
(10) Pub. No.: US 2026/0319442 A1
(43) Pub. Date: Oct. 15, 2026

(54) METHOD FOR TESTING AND MANUFACTURING BALANCE SPRINGS FOR TIMEPIECES

(71) Applicant: RICHEMONT INTERNATIONAL SA, Villars-sur-Glâne (CH)

(72) Inventors: Kevin SOOBBARAYEN, Villars-sur-Glâne (CH); Susana TOBENAS, Villars-sur-Glâne (CH)

(21) Appl. No.: 18/996,918

(22) PCT Filed: Jul. 17, 2023
(86) PCT No.: PCT/EP2023/069829

§ 371 Date: Jan. 17, 2025

(30) Foreign Application Priority Data
Jul. 18, 2022 (EP) 22185552.1

(51) Int. Cl. G04D 7/10; G04D 3/00; G06F 30/27

(52) U.S. Cl. CPC G04D 7/10; G04D 3/0089; G06F 30/27

(57) ABSTRACT

A method for controlling a hairspring or a hairspring blank arranged to form a hairspring, the control method comprising the following steps: applying to the hairspring or the hairspring blank a vibratory excitation varying over time to cover a predetermined frequency range, identifying at least one characteristic of a resonance frequency of the hairspring or the hairspring blank, such as a resonance peak, upon or in response to vibrational excitation over the predetermined frequency range, and subjecting to a thermal coefficient prediction machine the resonance frequency characteristic identified in step b. to determine a thermal coefficient of the Young's modulus (CTE) of the hairspring and/or a thermal coefficient (CT) of a horological system comprising the hairspring.

### TECHNICAL FIELD

The present invention relates to the field of control and manufacture of parts for watchmaking. The invention relates more particularly to a method for controlling and manufacturing timepiece hairsprings, otherwise called resonators.

### STATE OF THE ART

Mechanical watch movements are regulated by means of a mechanical regulator or oscillator comprising a resonator, that is to say an elastically deformable component whose oscillations determine the rate of the watch. For example, many watches include an oscillator comprising a hairspring as a resonator, mounted on the axis of a balance wheel and oscillated by an escapement. The natural frequency of the balance wheel-hairspring pair is used to regulate the rate of the watch and depends on several parameters, in particular the stiffness of the hairspring and the operating temperature.

Indeed, the frequency f of the regulating member formed by the hairspring of stiffness R coupled to a balance wheel of inertia I is given by the formula:

$$F = \frac{1}{2 π} \sqrt{\frac{R}{I}} \qquad [ equation 1 ]$$

The stiffness of the hairspring also defines its intrinsic vibration characteristics, such as the natural frequency and the resonance frequencies. In the present application, the natural frequency of an elastic system (a resonator alone or a resonator-balance wheel pair) is the frequency at which this system oscillates when it is in free evolution, that is to say without an exciting force. Moreover, a resonance frequency of an elastic system (for example the resonator alone) subjected to an exciting force is a frequency at which a local maximum of displacement amplitude can be measured for a given point of the elastic system. In other words, if the elastic system is excited with an excitation source of variable frequency over time, the displacement amplitude follows an upward slope before this resonance frequency, and follows a downward slope after, at any point which does not correspond to a vibration node. Typically, in such a test, the recording of the displacement amplitude as a function of the excitation frequency has a displacement amplitude peak or resonance peak which is associated with or characterizes the resonance frequency.

The stiffness of a hairspring resonator typically depends on the characteristics of the material it is made of, as well as its dimensions and in particular the thickness (that is to say the width) of its turns along its bar. The stiffness is given more specifically by:

$$R = \frac{M}{φ} \qquad [ equation 2 ]$$

with:
φ, the torsion angle of the spring, and
M, the return torque of the hairspring,
where M, for a bar of constant section made of a specific material, is given by:

$$M = \frac{E ( \frac{{e}^{3} h}{12} φ )}{L} \qquad [ equation 3 ]$$

with:
E, the Young's modulus of the material used for the bar,
L, the length of the bar,
h, the height of the bar, and
e, the thickness or width of the bar.

As will be explained in more detail below, the operating temperature is an influential parameter on the operation of the regulating member, equation 1 can be derived with respect to the temperature T, and we find:

$$CT = \frac{1}{2} ( CTE - 3 {α}_{S} - 2 {α}_{B} ) \qquad [ equation 5 ]$$

With:
T, the current temperature,
T₀, a reference temperature,
α_{S}, the coefficient of thermal expansion of the hairspring
α_{B}, the coefficient of thermal expansion of the felloe of the balance wheel.

This equation 4 can be rewritten as below:

$$\frac{1}{F} \frac{dF}{dT} = \frac{1}{2} ( \frac{1}{E ( {T}_{0} )} \frac{dE}{dT} + 3 {σ}_{S} - 2 {α}_{B} ) \qquad [ equation 4 ]$$

With:
CT: the thermal coefficient of the oscillator (seconds per day and per degree),
CTE: thermal coefficient of the Young's modulus (K⁻¹), or otherwise called thermoelastic coefficient.

The natural frequency of the regulating member formed by the hairspring of stiffness R coupled to a balance wheel of inertia I is in particular proportional to the square root of the stiffness of the hairspring. The main specification of a hairspring is its stiffness, which must be within a well-defined interval in order to be able to be paired with a balance wheel, which forms the inertial element of the oscillator. This pairing operation is essential to precisely adjust the frequency of a mechanical oscillator.

The importance of magnetic fields in the modern environment has led watchmakers to use silicon hairsprings in recent years, which are less sensitive to magnetic disturbances than metal hairsprings.

Very advantageously, several hundred silicon hairsprings can be manufactured on a single wafer using micro-fabrication technologies. It is known in particular to produce a plurality of silicon resonators with very high precision using methods of photolithography and machining/etching in a silicon wafer. The methods for producing these mechanical resonators generally use monocrystalline silicon wafers, but wafers made of other materials can also be used, for example polycrystalline or amorphous silicon, other semiconductor materials, glass, ceramic, carbon, carbon nanotubes or a composite comprising these materials. In turn, monocrystalline silicon belongs to the cubic crystalline class m3m whose thermal expansion coefficient (alpha) is isotropic.

It is very important that the characteristics of the oscillator are as stable as possible, in order to have a watch rate that is also stable, with in particular the least possible differences in rate depending on the operating temperature (summer-winter, wristwatch worn or not worn).

Silicon has a very negative value of the first thermoelastic coefficient, and consequently, the stiffness of a silicon resonator, and therefore its natural frequency, varies greatly depending on the temperature. In order to at least partially compensate for this disadvantage, documents EP1422436, EP2215531 and WO2016128694 describe a hairspring-type mechanical resonator made from a core (or two cores in the case of WO2016128694) made of monocrystalline silicon and whose temperature variations of the Young's modulus are compensated by a layer of amorphous silicon oxide (SiO2) surrounding the core (or cores), the latter being one of the rare materials having a positive thermoelastic coefficient. As shown in equation 5 above, temperature variations can lead to variations in the rate with the thermal coefficient CT which depends in particular on the thermal coefficient of the Young's modulus, the thermal coefficient of expansion of the hairspring and the thermal coefficient of expansion of the felloe of the balance wheel. Silicon hairsprings and their thermo-compensation therefore allow to adjust the terms of equation 5 relating to the hairspring to obtain a thermal coefficient CT of the oscillator. By extension, it is also possible to characterize the CT of a larger horological system, which integrates the hairspring, going up to the CT of a complete caliber, by determining the thermal drift of the caliber integrating that of the escapement, the gear train, including the influence of lubrication. In this perspective, the hairspring is considered to be the only adjustment variable to obtain a CT of the horological system which integrates it, as low as possible.

When silicon or other material hairsprings are produced by mass manufacturing on a wafer, the final functional yield will be given by the number of hairsprings whose stiffness corresponds to the pairing interval, divided by the total number of hairsprings on the wafer.

However, the micro-manufacturing steps, and more particularly the etching steps, used in the manufacture of hairsprings on a wafer typically result in a significant geometric dispersion between the dimensions of the hairsprings on the same wafer, and therefore a significant dispersion between their stiffnesses, notwithstanding that the etching pattern is the same for each hairspring. The measured stiffness dispersion normally follows a Gaussian distribution. In order to optimize the manufacturing yield, therefore focus is on centering the mean of the Gaussian distribution on a nominal stiffness value and also on reducing the standard deviation of this Gaussian.

In addition, the stiffness dispersion is even greater between hairsprings of two wafers etched at different times following the same method specifications. This phenomenon is shown in FIG. 1 where the stiffness dispersion curves Rd1, Rd2 and Rd3 for hairsprings on three different wafers are illustrated. Generally, for each wafer the stiffness distribution R (with respect to the number of hairsprings N with this stiffness) follows the normal or Gaussian law, with each dispersion curve being centered on its respective mean value Rm1, Rm2 and Rm3.

Documents WO2015113973 and EP3181938 propose to overcome this problem by forming a hairspring with dimensions greater than the dimensions necessary to obtain a hairspring of a predetermined stiffness, by measuring the stiffness of this hairspring formed by coupling it with a balance wheel having a predetermined inertia, by calculating the thickness of material to be removed to obtain the dimensions necessary to obtain the hairspring with the predetermined stiffness, and by removing this thickness from the hairspring. Similarly, document EP3181939 proposes to overcome this same problem by forming a hairspring with dimensions smaller than the dimensions necessary to obtain a hairspring of a predetermined stiffness, by determining the stiffness of this hairspring formed by coupling it with a balance wheel having a predetermined inertia, by calculating the thickness of material to be added to obtain the dimensions necessary to obtain the hairspring with the predetermined stiffness, and by adding this thickness of material to the hairspring.

In this way, as demonstrated in FIG. 2, notwithstanding the average stiffness Rm1, Rm2, etc. of the stiffnesses on a given wafer, the stiffness dispersion curve Rd1, Rd2, etc. can be recentered with respect to a nominal stiffness value Rnom.

This approach requires high precision in measuring the frequency of the hairspring to determine its stiffness. In particular, measurement errors can be caused by the balance wheel with predetermined inertia, or by the assembly carried out. A step must then be carried out to calculate the thickness to be removed in order to, again, remove the calculated thickness with high precision. In addition, it can be noted that coupling the hairspring with the balance wheel with a predetermined inertia requires meticulous operations requiring a long preparation time. Finally, it can also be noted that any assembly operation on parts or blanks still present on a wafer significantly increases the risk of pollution (for example, the presence of fine silicon particles (debris) produced during handling operations).

The present invention aims at proposing an approach free from the above disadvantages, which allows a faster production flow and/or with less risk of pollution(s), and/or a larger sampling, and/or a more precise measurement of the thermal coefficient of the Young's modulus (CTE) of the hairspring and/or of the thermal coefficient (CT) of a horological system comprising the hairspring, and therefore a more individualized correction of the hairsprings of the wafer to obtain horological systems whose operation is little or not disturbed by temperature variations.

### DISCLOSURE OF THE INVENTION

More specifically, a first aspect of the invention relates to a method for controlling a hairspring or a hairspring blank arranged to form a hairspring, the control method comprising the following steps:
a. applying to the hairspring or the hairspring blank a vibratory excitation varying over time to cover a predetermined frequency range,
b. identifying at least one characteristic of a resonance frequency of the hairspring or the hairspring blank, such as a resonance peak, upon or in response to vibrational excitation over the predetermined frequency range,
c. subjecting to a thermal coefficient prediction machine the resonance frequency characteristic identified in step b. (and preferably said at least one characteristic of a resonance frequency of the hairspring or the hairspring blank, such as a resonance peak identified in step b.), to determine a thermal coefficient of the Young's modulus (CTE) of the hairspring and/or a thermal coefficient (CT) of a horological system comprising the hairspring.

The method according to the above implementation comprises a step of vibratory excitation of the hairspring or the hairspring blank and the measurement of a characteristic of a resonance frequency, to then deduce by prediction a thermal coefficient of the Young's modulus (CTE) of the hairspring and/or a thermal coefficient (CT) of a horological system comprising the hairspring. There is no assembly with a balance wheel or another component, which saves time. In addition, the measurement is carried out on the hairsprings or the blanks alone, which limits the errors induced by other components or their assembly, as well as possible pollution. The measurement accuracy is improved because there are fewer sources of variability due to other components or pollution. In other words, the hairspring or the hairspring blank is tested alone. The vibratory excitation is applied to the part or to the single blank, not coupled to any balance wheel, weight or oscillating system. The method allows to control single and free parts (that is to say with at least one free end, not attached to any mechanism or balance wheel), which brings at least advantages of productivity gains (no assembly with an oscillating system), quality gains (no pollution of parts, nor breakage, and more parts can be tested in the same budget), a gain in precision (no error related to other components of an oscillating system).

It will be noted that the determination of the thermal coefficient of the Young's modulus (CTE) of the hairspring or of the hairspring blank by the method according to the invention is well suited for oxidized parts for which the thickness of the oxide layer is not precisely known at this stage of the manufacturing method. With the present invention, it is easy to obtain the thermal coefficient of the Young's modulus (CTE) of the oxidized hairspring or of the oxidized hairspring blank, which are in a way composite parts (core made of silicon, with a shell made of silicon oxide).

According to one embodiment, the vibrational excitation can be carried out with a shock device that applies an excitation to the part to be tested in a relatively short time. In other words, it is possible to impose a displacement or an acceleration on the parts to be tested in a very short time (over a period of less than one second, less than 500 ms, less than 100 ms, less than 10 ms). In particular, the shock device can apply a shock to the hairspring or its support to vibrate the parts. An impact hammer or any device with a moving mass can be used. In the case of parts attached to a wafer, it is possible to apply the shock to the wafer, or to a fitting supporting the wafer. Depending on the part to be tested and its position on the wafer, it is possible to apply the shock to a particular location on the wafer and/or in a particular direction. The parts vibrate and the vibration response can be recorded over time, to extract resonance peaks and their frequencies from this measurement, for example with a Fourier transform.

According to one embodiment, the horological system comprising the hairspring may comprise:
the hairspring, and a balance wheel,
the hairspring, a balance wheel, and an escapement device, such as an anchor escapement,
the hairspring, a balance wheel, an escapement device, and a gear train, such as a finishing gear train,
the entire movement of the watch, including the hairspring.
   In all of the above cases, it is possible to know in advance the value of the thermal coefficient of the parts other than the hairspring, or at least their contribution to the thermal coefficient of the horological system. In practice, these values are standard and known in advance depending on the references or components chosen, and in the case of a silicon hairspring, it is possible to adjust the contribution of the hairspring in equation 5 above to obtain a thermal coefficient of the horological system that will be within a range of values and/or within a desired tolerance(s).

According to one embodiment, the vibrational excitation is applied to the hairspring or the hairspring blank having a free end (typically the central collet) and another end fixed to the wafer or to a clamp. From a mechanical point of view, it can be considered schematically that the vibrational excitation is applied to a mass (located at the center of gravity of the hairspring) connected to a reference frame (a gripping clamp for a hairspring alone, or the remainder of a substrate or a plate for a blank for example made of silicon and not detached) by a spring (the elastic portion of the hairspring). The vibrational excitation moves the suspended mass. In other words, the vibrational excitation is applied to the hairspring alone or to the hairspring blank alone.

It can also be noted that if it is determined that a dimensional correction and/or additional processing operation(s) must be made to the tested part (or to all the single parts attached to the same wafer, or to the single parts attached to an area of a wafer, including or not the tested part), this can be done on the single part(s) without re-disassembling anything (for example, it can be provided to apply oxidation directly to a silicon part at the end of the test). It is therefore possible to add or remove material to the single part(s), to carry out doping to vary intrinsic values (stiffness, Thermal coefficient of the Young's modulus (CTE) of the hairspring). In other words, the dimensional correction and/or additional processing operation(s) are carried out on the single part(s).

The method according to the above implementation therefore allows to test hairspring blanks during manufacture while limiting the risks of pollution or assembly errors. A dimensional correction (of section, height and/or thickness) and/or additional processing operation(s) are then possible. The method according to the above implementation also allows to test finished hairsprings, for example to classify by stiffness increments, or to plan a pairing with a particular balance wheel.

According to one embodiment,
step b. may comprise:
   b 1. a first identification step which may comprise identifying a first characteristic of a first resonance frequency such as a first resonance peak,
   b 2. a second identification step which may comprise identifying a second characteristic of a second resonance frequency such as a second resonant peak, the second resonance frequency being different from the first resonance frequency,
and step c. may comprise:
   c 1. a first prediction step which may consist in subjecting to another prediction machine the first characteristic of the first resonance frequency to determine a parameter different from the thermal coefficient of the Young's modulus (CTE) of the hairspring and/or the thermal coefficient (CT) of a horological system comprising the hairspring, such as a stiffness or a defect of the hairspring or the hairspring blank,
   c 2. a second prediction step which may consist of subjecting to the thermal coefficient prediction machine the second characteristic of the second resonance frequency to determine the thermal coefficient of the Young's modulus (CTE) of the hairspring and/or the thermal coefficient (CT) of a horological system comprising the hairspring.

According to the above embodiment, the first resonance frequency is used to determine a parameter different from the thermal coefficient of the Young's modulus (CTE) of the hairspring and/or the thermal coefficient (CT) of a horological system comprising the hairspring, such as for example a stiffness or a defect of the hairspring or the hairspring blank. The second resonance frequency is used to determine the thermal coefficient of the Young's modulus (CTE) of the hairspring and/or the thermal coefficient (CT) of a horological system comprising the hairspring. In other words, two different frequencies are retained or identified to predict or calculate two distinct parameters (stiffness or presence of a defect on the one hand, the thermal coefficient of the Young's modulus (CTE) of the hairspring and/or the thermal coefficient (CT) of a horological system on the other hand).

According to one embodiment, said other prediction machine may be provided to identify a defect requiring rework or scrapping of the part in question. According to this implementation, the hairspring with the identified defect cannot be used at all or cannot be used without physical rework of its geometry and/or its composition and/or its material. In other words, if a defect is identified or determined, a step of isolating and/or setting the part aside may be provided, for a physical rework on the part in question (modification or scrapping). The part then follows a manufacturing circuit dedicated to non-compliant parts, which includes a rework or scrapping step.

According to one embodiment, steps b1 and b2 may be separated by a thermo-compensation step such as an oxidation step, and step a. may comprise:
a1. a first step of vibrational excitation, which can be carried out before step b1. and consisting of applying to the hairspring or the hairspring blank a first vibrational excitation that is variable over time to cover a first predetermined frequency range,
a2. a second vibrational excitation step, which can be carried out before step b2. and consisting of applying to the oxidized hairspring or to the oxidized hairspring blank a second vibrational excitation that is variable over time to cover the first predetermined frequency range or a second predetermined frequency range.

According to the above implementation, the first vibrational excitation step is used to determine a stiffness or the presence of a defect, and the second vibrational excitation step is used to determine the thermal coefficient of the Young's modulus (CTE) of the hairspring and/or the thermal coefficient (CT) of a horological system. Different vibrational excitations can be imposed between steps a1 and a2.

According to one embodiment,
step a. may be implemented after an oxidation step,
and steps b1. and b2. may take into account or may be based on the same vibrational response of the hairspring or the hairspring blank. In other words, a first portion of the vibrational response is used to identify the first resonance frequency and a second portion of the same vibrational response is used to identify the second resonance frequency.

According to one embodiment:
the first resonance frequency can be chosen to be a resonance frequency of a plane resonance mode, preferably for high resonance frequencies, for example greater than 40 kHz, or greater than 60 KHz, and/or
the second resonance frequency can be chosen to be a resonance frequency of an out-of-plane resonance mode.

According to the above implementation, a plane resonance mode can be considered to be a resonance mode in which the different portions of the hairspring or the hairspring blank are mainly displaced in the plane of the part at rest. If this plane is defined by directions X and Y, with a direction Z normal to the plane, then the displacements in X or Y are greater than or equal to the displacements in Z. In an out-of-plane resonance mode, the displacements in Z are greater than or equal to the displacements in X or Y, and preferably the displacements in Z are two to three times greater than the displacements in X or Y. The applicant has noticed that an oxidized part can have significantly different out-of-plane resonance mode frequencies compared to the same non-oxidized parts. Consequently, to predict a thermal coefficient of the Young's modulus (CTE) of the hairspring and/or a thermal coefficient (CT) of a horological system comprising the hairspring accurately, it may be preferable to take into account an out-of-plane resonance mode.

According to one embodiment, the first resonance frequency may be lower than the second resonance frequency and/or:
the first resonance frequency may be chosen in a range of values from 0 Hz to 100 kHz, preferably from 0 Hz to 50 kHz, more preferably from 0 Hz to 40 kHz, and very preferably from 10 KHz to 35 kHz, and/or
the second resonance frequency may be chosen in a range of values from 0 Hz to 300 kHz, preferably from 50 KHz to 250 kHz, more preferably from 60 kHz to 200 kHz, and very preferably from 100 KHz to 200 kHz. The applicant has noticed that an oxidized part may have significantly different resonance mode frequencies compared to the same non-oxidized parts for resonance frequencies greater than 40 kHz, preferably greater than 50 KHz and very preferably greater than 60 KHz. Therefore, to predict a thermal coefficient of the Young's modulus (CTE) of the hairspring and/or a thermal coefficient (CT) of a horological system comprising the hairspring accurately, it may be preferable to take into account resonance modes with high resonance frequencies.

According to one embodiment, step b. may consist of identifying a characteristic of a resonance frequency sensitive to the thermal coefficient of the hairspring or the hairspring blank.

Of course, the frequency range of the spectrum obtained does not only depend on the source of vibrational excitation but also on the sensor of the measuring instrument used. Thus, the frequency range is related both to the excitation frequency range and to the frequency range over which the oscillation amplitude measuring instrument (vibrometer or the like) is sensitive. However, the excitation frequency range will be chosen so as to include at least one resonance frequency of the tested hairspring or blank.

The predetermined resonance frequency that the finished hairspring must have may be a target natural frequency or a target resonance frequency, or a range of target natural frequency, or a range of target resonance frequency defined by a tolerance around a target value.

In the above method, the characteristic of a resonance frequency is a characteristic of the oscillatory response measured over a predetermined frequency range, comprising at least one resonance frequency. Such a characteristic is typically identified after processing a raw measurement signal (for example measuring the amplitudes or speeds or accelerations of displacement of certain points of the hairspring or of the hairspring blank), the processing being able to include for example a Fourier transform to identify resonance peaks and therefore resonance frequencies.

It may be noted that the method may determine a thermal coefficient of the Young's modulus (CTE) of the hairspring and/or a thermal coefficient (CT) of a horological system comprising the hairspring in order to classify the part, and/or to provide for a pairing with other particular components and/or to then calculate/deduce a dimensional correction and/or an additional processing operation(s) to be applied in order to obtain a target thermal coefficient of the Young's modulus (CTE) of the hairspring and/or a target thermal coefficient (CT) of a horological system comprising the hairspring. However, only the identified resonance frequency may be taken into account in order to directly calculate/deduce a dimensional correction and/or an additional processing operation(s) to be applied in order to obtain a target thermal coefficient of the Young's modulus (CTE) of the hairspring and/or a target thermal coefficient (CT) of a horological system comprising the hairspring.

According to one embodiment, in step a, the frequency range is applied simultaneously to a plurality of hairsprings or hairspring blanks. Speed is improved because the vibrational excitation can typically be imposed on a wafer supporting several hundred hairspring blanks, which would for example still be attached to the wafer.

According to one embodiment, the frequency range is predetermined to encompass at least one range of frequencies:
centered on the predetermined resonance frequency, and
having an extent of at least 30% of the predetermined resonance frequency, that is to say ±15% of the predetermined resonance frequency. For example, if the predetermined resonance frequency is 1 kHz, then the frequency range will be from 850 Hz to 1150 Hz.

In one embodiment, the hairspring may have at least two expected predetermined resonance frequencies, and the frequency range is predetermined to cover at least the two expected predetermined resonance frequencies. By covering or sweeping a wide range of frequencies, multiple resonant peaks (or resonance frequencies) can be measured, which can provide improved accuracy.

According to one embodiment, step a comprises the use of a source, such as a piezoelectric source, allowing to induce or impose an acoustic excitation on a rim of a wafer supporting the hairspring blank, or preferably on, or else under the hairspring or the hairspring blank to be specifically excited.

According to one embodiment, the acoustic source can be coupled to an excitation cone chosen to excite at least one hairspring or one hairspring blank. Preferably, if a wafer supports several hairspring blanks, then the acoustic source can be coupled to an excitation cone chosen to excite at least a portion and preferably all the hairspring blanks.

According to one embodiment, the acoustic source can be chosen and/or adjusted to generate the vibrational excitation that is variable over time to cover the predetermined frequency range:
with an amplitude sufficient to generate vibrations of the hairspring or the hairspring blank of sufficient amplitude to be detected by the means for measuring the amplitude or speed or acceleration of displacement of at least one point of the hairspring or the hairspring blank and/or
for a sufficient duration to deduce vibration spectra of the hairspring or the hairspring blank.

According to one embodiment, step b comprises the use of an optical measuring means, such as a laser vibrometer by Doppler effect.

According to one embodiment, step b may be based on a measurement over time of an amplitude or a speed or an acceleration of displacement of at least one point of the hairspring or the hairspring blank, preferably carried out at least partially during step a.

According to one embodiment, step b comprises:
a step of identifying a resonance frequency of the hairspring or the hairspring blank according to an operational or modal deformation of at least one point of the hairspring or the hairspring blank. An operational or modal deformation is typically defined by an amplitude or speed of displacement or else an acceleration and a direction of oscillation (outside or in a particular plane) according to the excitation frequency.

According to one embodiment, the hairspring or the hairspring blank may be contained in a base plane, and step b may comprise:
a step b″ of measuring an amplitude or a speed or an acceleration of displacement of at least one point of the hairspring or the hairspring blank in a direction normal to the base plane, and/or
a step b′″ of measuring an amplitude or a speed or an acceleration of displacement of at least one point of the hairspring or the hairspring blank in a direction contained in the base plane.

Measurements of displacements or speeds in several directions allow better identification of resonance peaks and frequencies.

According to one embodiment, step b. may comprise:
a step of identifying a resonance peak of the hairspring or of the hairspring blank according to an amplitude or a speed of displacement of at least one point of the hairspring or of the hairspring blank.

According to one embodiment, the characteristic of the resonance frequency can be identified based on the width of the resonant peak, at mid-height of the maximum value of the resonant peak. This processing method allows to limit the calculation errors which could be made by relying only on the identification of the frequency position of the peak defined by its maximum value.

According to one embodiment, step b comprises a step of processing the measurement signal with, for example, a Fourier transform, to identify resonance peaks of displacement or speed or acceleration, and/or phase amplitude, according to the excitation frequency.

According to one embodiment, the thermal coefficient prediction machine may be a calculation machine for predicting or calculating from the frequency characteristics the thermal coefficient of the Young's modulus (CTE) of the hairspring and/or the thermal coefficient (CT) of a horological system comprising the hairspring. In other words, the prediction machine is not a regulated or self-regulated or feedback loop system for adjusting a resonance frequency in response to a measurement and a comparison with a target value.

In other words, the prediction machine is a calculation machine, which may be a calculation unit intended to implement one or more mathematical formulas to predict a Thermal coefficient of the Young's modulus (CTE) value of the hairspring and/or a thermal coefficient (CT) value of a horological system comprising the hairspring, when it receives as input a value of a physical characteristic measured on the hairspring or the hairspring blank.

According to one implementation, the prediction machine, for example the calculation unit, can be provided to implement one or more mathematical formulas (for example with a polynomial distribution) constructed by linear regression from experimental or simulation data.

According to one implementation, the prediction machine, for example the calculation unit, may be a prediction machine using artificial intelligence software.

According to one implementation, the prediction machine, for example the calculation unit, may be a prediction machine using at least one neural network designed to receive as input values or graphs taken from the spectra of vibration measurements and designed to give as output a thermal coefficient of the Young's modulus (CTE) of the hairspring and/or a thermal coefficient (CT) of a horological system comprising the hairspring.

According to one embodiment, the thermal coefficient prediction machine can implement a classification performed for example by a neural network to predict the thermal coefficient of the Young's modulus (CTE) of the hairspring and/or the thermal coefficient (CT) of a horological system comprising the hairspring.

According to one embodiment, the thermal coefficient prediction machine can implement a regression method, for example a linear regression to predict the thermal coefficient of the Young's modulus (CTE) of the hairspring and/or the thermal coefficient (CT) of a horological system comprising the hairspring.

According to one embodiment, the thermal coefficient prediction machine can implement a classification based on a k-means or k-medians partitioning to predict the thermal coefficient of the Young's modulus (CTE) of the hairspring and/or the thermal coefficient (CT) of a horological system comprising the hairspring.

According to one embodiment, the control method may comprise a preliminary step of taking into account the material of the hairspring or the hairspring blank, and adjusting a maximum amplitude of the vibrational excitation and/or a range of frequencies of the predetermined frequency range according to the material of the hairspring or the hairspring blank.

According to one embodiment, if step c. determines that the thermal coefficient of the Young's modulus (CTE) of the hairspring and/or the thermal coefficient (CT) of a horological system comprising the hairspring is outside an expected range of values, then the method may comprise at least one step of identifying or isolating or reworking or scrapping the hairspring or the hairspring blank.

According to one embodiment, if step c. determines that the thermal coefficient of the Young's modulus (CTE) of the hairspring and/or the thermal coefficient (CT) of a horological system comprising the hairspring is outside a range of expected values, then the method may comprise at least one step consisting in defining a step of processing the hairspring or the hairspring blank, such as a thermo-compensation, oxidation or deoxidation step, to obtain the thermal coefficient of the Young's modulus (CTE) of the hairspring and/or the thermal coefficient (CT) of a horological system comprising the hairspring within the range of expected values.

According to one embodiment, step a. is carried out for a plurality of hairsprings or hairspring blanks attached to a wafer, and if step c. determines that the thermal coefficient of the Young's modulus (CTE) of the hairspring and/or the thermal coefficient (CT) of a horological system comprising the hairspring is outside a range of values expected for first hairsprings or first hairspring blanks and within the range of values expected for second hairsprings or second hairspring blanks, then provision may be made to detach only the second hairsprings or second hairspring blanks and to provide a step of processing the first hairsprings or first hairspring blanks, such as a thermo-compensation, oxidation or deoxidation step, to obtain the thermal coefficient of the Young's modulus (CTE) of the hairspring and/or the thermal coefficient (CT) of a horological system comprising the hairspring within the range of expected values. Provision may be made to reiterate these steps, by repeating or not steps a. and b.

According to one embodiment, step a and step b are repeated at least several times for the same measurement point of the hairspring or the hairspring blank.

According to one embodiment, step a and step b are synchronized. Such synchronization provides the possibility of detecting a phase shift, or an attenuation, or a coupling, the consideration of which can improve the accuracy of the prediction, or allow to adjust or recalibrate the source of vibrational excitation.

A second aspect of the invention may relate to a method for manufacturing a hairspring having at least one expected predetermined resonance frequency comprising the steps of:
A/forming at least one hairspring or a hairspring blank having dimensions comprised within predetermined tolerances necessary to obtain the expected predetermined resonance frequency,
B/controlling the hairspring or the hairspring blank according to the control method of the first aspect.

According to one embodiment, the manufacturing method may comprise a step consisting of:
C/identifying or isolating or reworking or discarding the hairspring or the hairspring blank formed in step A/, if step c. determines that the Thermal coefficient of the Young's modulus (CTE) of the hairspring and/or the thermal coefficient (CT) of a horological system comprising the hairspring is outside an expected range of values.

According to one embodiment, the hairspring blank may be formed on a wafer, along with a plurality of other hairspring blanks.

A third aspect of the invention may relate to a prediction machine learning method to implement step c. of the control method according to the first aspect, comprising the steps of:
i—forming hairsprings or hairspring blanks and applying a thermo-compensation step thereto,
ii—applying to each of the hairsprings or each of the hairspring blanks a vibrational excitation that is variable over time (that is to say a variable vibrational excitation which encompasses, or preferably the same variable vibrational excitation as, that used during the control method) to cover a predetermined frequency range (that is to say a predetermined frequency range which encompasses, or preferably the same predetermined frequency range as, that used during the control method),
iii—identifying at least one characteristic of a resonance frequency (that is to say a characteristic of a resonance frequency which encompasses, or preferably the same characteristic of a resonance frequency as, that identified during the control method), of each hairspring or each hairspring blank when applying the predetermined frequency range and recording the temperature of the parts during step ii- and/or iii-,
iv′—mounting a plurality of hairsprings or hairspring blanks in an oscillating mechanism having a predetermined inertia so as to measure for each hairspring or hairspring blank a sustained oscillation frequency, and/or a rate of the horological system formed by, or comprising, the oscillating mechanism at least at one predetermined temperature and preferably at least at two predetermined temperatures,
and/or
iv″—modeling in a simulation tool a plurality of hairsprings or hairspring blanks in an oscillating mechanism having a predetermined inertia so as to calculate for each hairspring or hairspring blank a sustained oscillation frequency and/or a thermal coefficient of a horological system comprising the hairspring and/or the rate of the horological system comprising the hairspring at least at one predetermined temperature and preferably at least at two predetermined temperatures,
v—optionally, deducing at least one expected resonance frequency from the resonance frequency identified in step iii-, and/or from the sustained oscillation frequency and/or from the rate of the horological system measured in step iv′- and/or calculated in step iv″—
vi—deducing a thermal coefficient of the Young's modulus (CTE) of the hairspring and/or the thermal coefficient (CT) of a horological system comprising the hairspring from the measurements of step iv′—and/or the calculations of step iv″-
vii—providing the prediction machine, and for each hairspring or hairspring blank with:
   the characteristic of the resonance frequency identified in step iii-;
   optionally, the same characteristic of the expected resonance frequency;
   the temperature recorded during step ii- and/or iii-;
   the thermal coefficient of the Young's modulus (CTE) of the hairspring and/or the thermal coefficient (CT) of a horological system comprising the hairspring deduced in step vi-.

### BRIEF DESCRIPTION OF THE DRAWINGS

Other details of the invention will appear more clearly upon reading the following description, given with reference to the appended drawings in which:

FIG. 1 shows uncorrected stiffness dispersion curves for hairsprings on three different wafers,

FIG. 2 shows the centering of the average stiffness on a wafer around a nominal value,

FIGS. 3A-3F are a simplified representation of a method for manufacturing a mechanical resonator, here a hairspring, on a wafer,

FIG. 4 shows a device for evaluating the torque of a hairspring,

FIG. 5 schematically shows the implementation of the evaluation of the stiffness of a hairspring by vibration analysis,

FIG. 6 shows an example of frequencies applied to a silicon wafer supporting hairspring blanks, to impose a vibrational excitation,

FIG. 7 shows an example of measuring the displacement amplitudes of a point of a hairspring blank, in response to the imposed frequency range of FIG. 6,

FIG. 8 shows in detail a resonance peak identified at a particular frequency in FIG. 7,

FIG. 9 shows the measured and superimposed resonance peaks for the particular frequency of FIG. 8 for tested parts,

FIG. 10 shows an example of a prediction model built from data extracted from FIG. 9,

FIG. 11 shows the influence of temperature on the resonance frequency of a particular resonance mode,

FIG. 12 shows the sensitivity of the resonance frequency to the oxide thickness of a silicon hairspring.

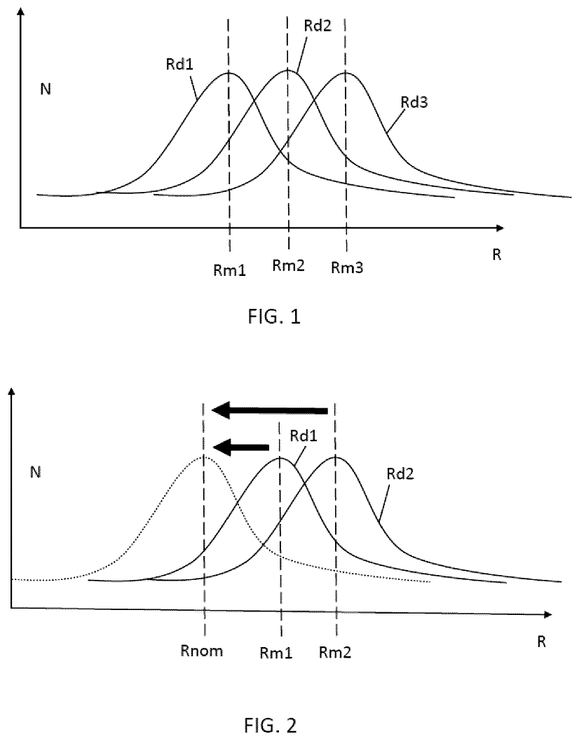

### EMBODIMENT OF THE INVENTION

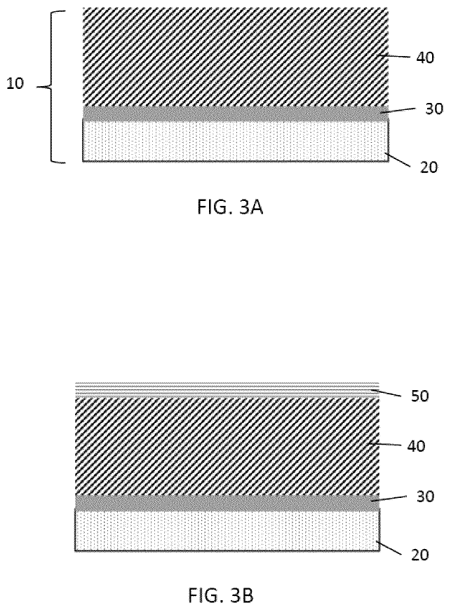

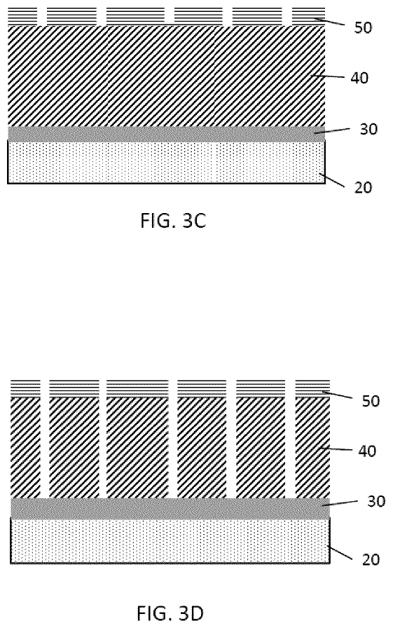

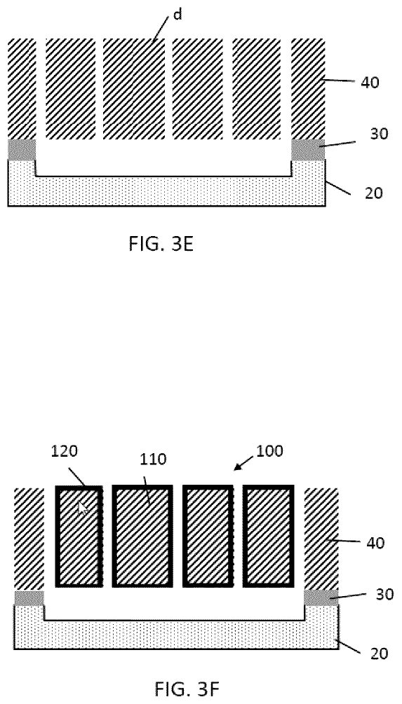

FIGS. 3A-3F are a simplified representation of a method for manufacturing a mechanical resonator 100 on a wafer 10. The resonator is in particular intended to equip a regulating member of a timepiece and, according to this example, is in the form of a silicon hairspring 100 which is intended to equip a balance wheel of a mechanical horological movement.

The wafer 10 is illustrated in FIG. 3A as a SOI (“silicon on insulator”) wafer and comprises a substrate or “handler” 20 carrying a sacrificial silicon oxide (SiO₂) layer 30 and a monocrystalline silicon layer 40. For example, the substrate 20 may have a thickness of 500 μm, the sacrificial layer 30 may have a thickness of 2 μm, and the silicon layer 40 may have a thickness of 120 μm. The monocrystalline silicon layer 40 may have any crystal orientation.

A lithography step is shown in FIGS. 3B and 3C. “Lithography” means the set of operations allowing to transfer an image or pattern on or above the wafer 10 to the latter. With reference to FIG. 3B, in this exemplary embodiment, the layer 40 is covered with a protective layer 50, for example made of a polymerizable resin. This layer 50 is structured, typically by a photolithography step using an ultraviolet light source as well as, for example, a photo-mask (or another type of exposure mask) or a stepper and reticle system. This structuring by lithography forms the patterns for the plurality of resonators in the layer 50, as illustrated in FIG. 3C.

Subsequently, in the step of FIG. 3D, the patterns are machined, in particular etched, to form the plurality of resonators 100 in the layer 40. The etching can be carried out by a Deep Reactive lon Etching technique (also known by the acronym DRIE). After the etching, the remaining portion of the protective layer 50 is subsequently removed.

In FIG. 3E, the resonators are released from the substrate 20 by locally removing the sacrificial layer 30 or even by etching all or a portion of the silicon of the substrate or handler 20. A smoothing (not shown) of the etched surfaces can also take place before the release step, for example by a thermal oxidation step followed by a deoxidation step, consisting for example of wet etching based on hydrofluoric acid (HF).

In the last step of the manufacturing method in FIG. 3F, the turns 110 of the silicon resonator 100 are covered with a layer 120 of silicon oxide (SiO2), typically by a thermal oxidation step to produce a thermo-compensated resonator. The formation of this layer 120, which generally has a thickness of 2-5 μm, also affects the final stiffness of the resonator and therefore must be taken into account during the previous steps to obtain vibrational characteristics of the hairspring leading to obtaining a particular natural frequency of the hairspring-balance wheel pair in a given watch mechanism.

As indicated above, at the stage preceding the production of the thermo-compensation layer, the different resonators formed in the wafer generally have a significant geometric dispersion between each other and therefore a significant dispersion between their stiffnesses, notwithstanding that the steps of forming the patterns and of machining/etching through these patterns are the same for all the resonators.

Moreover, this dispersion of stiffnesses is even greater between the hairsprings of two wafers etched at different times even if the same method specifications are used.

Finally, it should be noted that during manufacturing, more specific manufacturing defects may appear. For example, during the machining step of FIG. 3D, material may remain between two adjacent turns. Parts for which material residues are still present between the turns or the substrate, contrary to what is shown in FIG. 3E, can also be seen. Material bridges between two adjacent turns during the oxidation shown in FIG. 3F can also be formed. Finally, pollution can also occur with debris or particles that get stuck between two turns or the turns and the substrate. All these defects strongly affect the vibration behavior and cannot be corrected by adding or removing material from all the parts as is known to be done in the prior art.

The above description relates to silicon resonators 100, but it is possible to consider making the resonators from glass, ceramic, carbon nanotubes, or else metal. In particular, conventional steel or wafer-detached hairsprings can be tested. In this case, the metal hairspring or the wafer-detached hairspring is pinched or taken as a reference by a tool that positions it opposite the emission source and the displacement measurement apparatus.

As is known, the measurement of the stiffness of the hairspring can be carried out in a so-called static manner, that is to say without oscillating the hairspring, but by determining its torque. For example, reference may be made to document EP3654111.

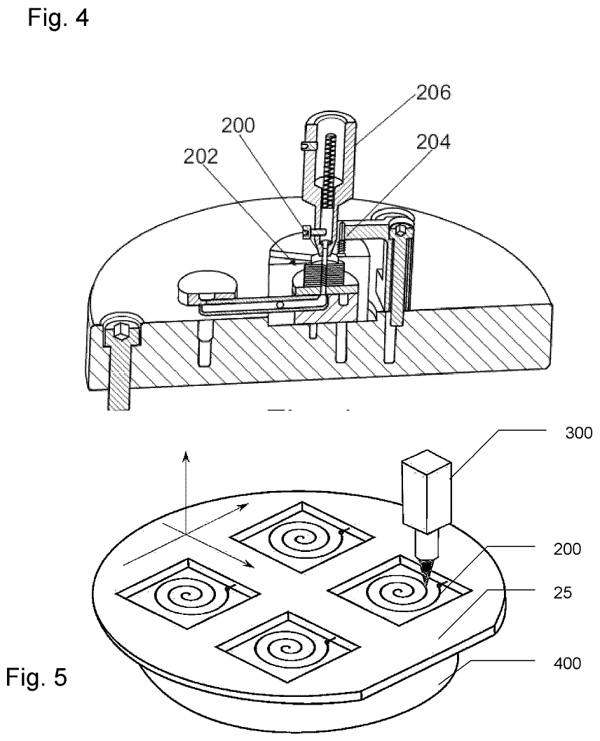

An alternative to the method described in the latter document consists in performing a torque measurement using a rheometer, as marketed by the company Anton Paar. A device provided for this purpose is illustrated in FIG. 4. Advantageously, it allows to place the hairspring 200 to be evaluated on a fitting 202, and to position it so that it can be fixed at its last turn by a holding member 204. Once the last turn is fixed, the fitting 202 is moved away from the hairspring 200 which is thus completely free of any elastic constraint. The head of the rheometer 206 is then positioned opposite the collet of the hairspring. It has a counter-form of the collet, non-circular, but with a reduced size, which allows the head of the rheometer to engage in the collet, with controllable precision, without contacting the hairspring. The head of the rheometer is then rotated, in a direction of contraction of the hairspring. When the head contacts the collet, it drives it and the rheometer measures the torque exerted by the elastic return of the hairspring, over a given angle. However, such a measurement remains a single measurement and requires a significant amount of handling time, with numerous risks of breakage, pollution, etc.

The present invention proposes to determine at least one characteristic of a resonance frequency of a sample of resonators 100 on the wafer in step 3F, to deduce a thermal coefficient of the Young's modulus (CTE) of the hairspring and/or a thermal coefficient (CT) of a horological system comprising the hairspring and optionally in step 3E, to deduce a stiffness and/or a structural defect. In particular, the present invention proposes to identify the above parameters without disassembling the wafer or measuring in a test subassembly, according to a more efficient method than the methods of the prior art.

Thus, the invention proposes to determine at least one characteristic of a resonance frequency of a sample of resonators by vibration measurement and to apply a predictive method (for example a numerical model or a classification or categorization method) to relate the result of said vibration measurement to the identification of the thermal coefficient of the Young's modulus (CTE) of the hairspring and/or the thermal coefficient (CT) of a horological system comprising the hairspring.

Thus, the modal properties of the hairspring attached to the wafer are exploited. During a learning phase, and by an analytical and numerical approach, it is possible to set up a prediction machine by establishing a predictive model relating the thermal coefficient of the Young's modulus (CTE) of the hairspring and/or the thermal coefficient (CT) of a horological system including the hairspring to certain frequencies (natural frequency or resonance frequencies associated with a resonance peak or a width at mid-height) specifically chosen.

Once the learning phase is completed (once the modes to be exploited and the excitation frequencies are determined), it is possible to move on to a prediction phase and use the prediction machine by exploiting the predictive model to control the resonators of a produced wafer, in order to predict the thermal coefficient of the Young's modulus (CTE) of the hairspring and/or the thermal coefficient (CT) of a horological system comprising the hairspring. The result of the prediction can be used to validate produced parts, and/or decide on additional processing to correct the thermal coefficient of the Young's modulus (CTE) of the hairspring and/or the thermal coefficient (CT) of a horological system comprising the hairspring and/or discard parts that are non-compliant in terms of the thermal coefficient of the Young's modulus (CTE) of the hairspring and/or the thermal coefficient (CT) of a horological system comprising the hairspring.

Thus, it is possible to integrate the control method into a manufacturing method to obtain parts that are clean to be reached, maintained, generate a specific and predetermined natural oscillation frequency independent of temperature variations, once the resonators are each coupled to a balance wheel of a given watch mechanism.

It should be noted that the prediction machine is a device that allows to predict, therefore to give or calculate in advance, from one or more measured resonance frequencies, values of the thermal coefficient of the Young's modulus (CTE) of the hairspring and/or of the thermal coefficient (CT) of a horological system comprising the hairspring, without coupling the hairspring to a balance wheel, and without carrying out tests at several temperatures. It can be expected that the prediction machine:
is based on a mathematical model (for example a polynomial law relating one or more resonance frequencies to the thermal coefficient of the Young's modulus (CTE) of the hairspring and/or to the thermal coefficient (CT) of a horological system comprising the hairspring),
uses a neural network to receive as input values or graphs taken from the spectra of vibration measurements to give as output a thermal coefficient of the Young's modulus (CTE) of the hairspring and/or a thermal coefficient (CT) of a horological system comprising the hairspring,
implements a system using artificial intelligence.

### Vibrational Excitation

Measuring the vibration response of resonators allows to deduce at least one characteristic of a resonance frequency, such as a value of a resonance frequency. In detail, a vibrational excitation must first be imposed on the wafer. Several options are available:
a. Measurements in the frequency domain:
1—using a piezoelectric source (or any other source allowing to induce or impose an acoustic excitation) on the rim of the wafer, on, or under the hairspring blank 200 to be specifically excited (preferred) which excites at a particular frequency f₀ (continuous single-frequency excitation). In this variant, the excitation is maintained.
2—Alternatively, the piezoelectric source (or any other source for inducing or imposing acoustic excitation) may also be used on the rim of the wafer, on, or under the hairspring blank 200 to be specifically excited (preferred) which excites at a frequency that is variable over time to cover a predetermined frequency range, ranging for example from 0 to 300 kHz, preferably from 0 to 275 kHz, preferably from 0 to 250 KHz, preferably from 5 kHz to 250 kHz, and preferably from 10 to 235 kHz. The entire frequency range may be swept or covered in a time interval that may range from a fraction of a second to a few seconds. For example, it may be provided to sweep or cover the range of frequencies of the frequency range in less than 0.5 s, less than 1 s, or less than 1.5 s. In this variant, the excitation frequency changes continuously.
b. Measurements in the time domain: using an excitation hammer (or any other source to induce an acoustic impulse excitation) on the rim of the wafer, on, or under the hairspring to be excited specifically (preferred) which gives the shortest possible acoustic impulse (multi-frequency impulse excitation). In this variant, the excitation is punctate and not sustained.

Moreover, measurements can be performed following a particular sampling, for example according to a sampling range of 4, 2 or 1 Hz. Indeed, the resolution for processing the acquisition data according, for example, to a Fourier transform depends directly on the duration of this acquisition.

Moreover, a signal sampling frequency of at least 600 kHz can be chosen if the frequency range extends up to 300 KHz for example. Generally, Shannon's theorem which advises choosing a sampling frequency greater than twice the maximum frequency present in the measured signal can be followed.

In general, it is finally possible to change the direction of excitation, that is to say the direction of the movements imposed by the source (vibrations can be imposed in one or more axial directions, and this or these directions can be changed over time). In the case where a wafer comprising a plurality of resonators is excited, it is possible to adjust the direction of the vibrations so as to point at either one of the resonators, depending on the measurements of the displacement amplitude described below.

Finally, it is possible to couple the acoustic source to a divergent cone directed towards the resonators to be excited, and to adjust the acoustic source to emit an excitation signal with an amplitude sufficient to impose a vibrational excitation of the resonator(s) and having an amplitude sufficient to be detected and measured precisely by the chosen measuring instruments.

### Measurement of Amplitude or Speed, or Acceleration of Displacement

During excitation, the amplitude and phase (relative to the excitation source) of oscillation in the 3 directions X, Y (in the plane) and Z (out of plane) of the specifically excited hairspring are recorded using a suitable measuring means. The following possible measuring means may be mentioned, without limitation:
Optical methods by interferometry:
a. By 3D Doppler effect (laser vibrometer by Doppler effect),
b. Holographic,
Stroboscopic optical methods,
High temporal resolution chromatic confocal profilometry,
Optical reflectometry:
a. Vibration analysis by beam deflection on multi-dial detector or camera,
b. Analysis by TCSPC-type temporal analysis,
Acoustic methods by ultrasound by Doppler effect.

FIG. 5 schematically shows a silicon wafer 25 on which a plurality of hairspring blanks 200 are formed. A vibrational excitation source 400 is coupled to the wafer 25, so as to be able to impose a vibrational excitation. Consequently, each hairspring blank 200 will vibrate, and a laser vibrometer 300, here focused on a point of the hairspring blank 200 on the right, will be able to measure the vibration amplitudes of the measurement point over time. It is possible to measure the displacements in a direction normal to the plane of the wafer 25, but it is just as possible to measure the displacements in one or more directions contained in the plane of the wafer 25.

Once a particular point has been studied, the laser vibrometer 300 can be displaced to another measurement point on the hairspring blank 200, or moved to another hairspring blank 200 on the wafer 25. Of course, the hairspring blank 200 can alternatively be displaced relative to the laser vibrometer.

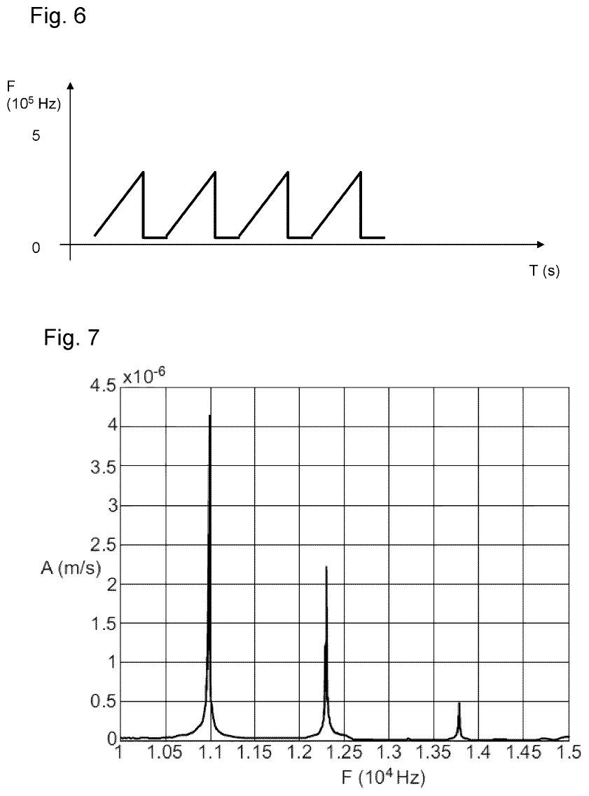

FIG. 6 shows an example of vibrational excitation over time. In the example given, the excitation frequency varies over time, between 0 Hz and 50 kHz (but it is possible to go up to 300 kHz), and a succession of rising edges can be imposed, each spaced by a rest period without excitation. For each measurement point on the hairspring blank 200, a plurality of rising edges can be imposed (between 2 rising edges and 60 rising edges), each lasting between 0.5 s and 2 s for example.

### Selecting Reference Points to be Measured

With regard to the displacement amplitude measurement, during the learning phase, provision can be made of a step consisting in identifying points of the resonator for which the vibration response is significant. Indeed, in the case of a hairspring to which a vibration is imposed, especially if the frequency varies over time, the vibration response will cause nodes to appear on the hairspring, that is to say particular points of the hairspring whose displacement amplitude is low or zero. If a displacement measurement is carried out on a point of the hairspring which turns out to be a node at one or more particular frequency (ies), the identification of resonance frequency characteristics will be negatively affected.

Thus, it is advantageous to provide a preliminary step of measuring displacement on a plurality of predetermined points of the hairspring, for example at least ten predetermined points, preferably at least twenty predetermined points, and very preferably at least thirty predetermined points. It is possible to provide for selecting the predetermined points arranged on an orthonormal reference frame X-Y in the plane of the hairspring.

At the end of this preliminary step of measuring amplitude on the predetermined points, it is possible to provide for identifying for each measurement point resonance frequencies, and then a step of selecting reference points for which the measurement of displacement amplitude during the excitation shows that they are not nodes at these resonance frequencies. In other words, the identified nodes have, at least at one resonance frequency, a displacement amplitude of zero or less than a first threshold peak value, and these points forming nodes are separated from the reference points to be considered for the subsequent measurements. It can also be noted that the reference points are different depending on the position of the hairspring blank 200 on the wafer 25.

Typically, it can be considered that at least two reference points will be selected, and preferably at least four reference points will be selected. In the case where the resonator has a radius Ra and is anchored or embedded on the wafer by its outer end of the stud, it is preferable to select four reference points chosen and located:
in a first area at less than 0.20×Ra (for example on the central collet), or
in a second area between 0.05×Ra and 0.30×Ra (for example on the second coil starting from the collet), or
in a third area between 0.35×Ra and 0.65×Ra (for example on a coil located in the middle of the hairspring), or
in a fourth area between 0.65×Ra and 0.85×Ra (for example on a coil located three-quarters of the way down the hairspring).

Thus, the reference points are far from the portion anchored on the wafer and naturally have a significant oscillatory displacement capacity, which ensures better precision of the displacement measurement.

Moreover, the displacements of a point on the body of the wafer, and/or a point on the excitation source, can also be measured to identify or measure, for example, a phase shift or vibration attenuation, or a resonance resulting from vibration coupling or from the wafer. These additional measurements allow to ensure that the peaks identified are indeed those of the hairspring alone. The measurement of the displacement amplitude and the vibrational excitation can also be synchronized.

Alternatively, it is possible to plan to measure the displacements/movements/vibrations only at a particular point preferably located on an area of the part that does not deform. In particular, it is possible to plan to point the measurement at a point on the collet of the hairspring or the hairspring blank. Indeed, the collet can be considered non-deformable during vibrational excitation and all points of the collet have similar displacements/movements/vibrations. Consequently, a small error in the location of the measurement point on the collet will have little impact on the final result. Moreover, by having chosen a particular measurement point on the part, it is possible to identify and choose a particular range of frequency to conduct the stiffness prediction.

According to an embodiment in which several parts still attached to a substrate or to a tool are to be tested in series, it is possible to provide:
a step of capturing an image of the parts to be tested,
a step of analyzing the image, for example, to recognize each type of part, and/or the position of each part,
a step of selecting one or more points to be measured for each part, and/or of selecting an excitation vibration spectrum to be imposed for each part and/or each selected point,
for each part to be tested, a step of positioning the substrate or the tool supporting the parts to be tested in a vibrational excitation and measurement apparatus. According to this implementation, the excitation and measurement can be automated in the case of a wafer that still carries the hairspring blanks:
one or more images of the wafer are taken,
an automatic image analysis is performed to know at least the position X-Y of each part (it is also possible to recognize the type or model of the part),
depending on the position and/or type of the part recognized, specific pre-established measurement points are identified or selected (for example on the collet), a specific excitation cycle can also be selected depending on the type of the part or a specific point,
with for example a tool that carries the wafer and that comprises a movable table in X-Y, each hairspring blank is successively automatically placed opposite the excitation source and the measurement apparatus to be tested by targeting the correct measurement point and applying the correct excitation specification.

According to one embodiment, depending on the measurement point selected on the part to be tested and/or depending on the excitation frequency, and/or depending on the model of the part to be tested, provision can be made of a step consisting of giving a particular orientation to the excitation direction and/or to the measurement direction. For this purpose, an excitation direction (or an axial direction of the excitation source) perpendicular to the part to be tested can be chosen to maximize the displacements perpendicular to the plane formed by the part at rest. An excitation direction (or an axial direction of the excitation source) inclined relative to the part to be tested can be chosen to maximize displacements contained in the plane formed by the part at rest. With regard to the measurement, a measurement direction (or an axial direction of a laser beam of the measurement apparatus) perpendicular to the part to be tested can be chosen to maximize the measurement accuracy of the displacements perpendicular to the plane formed by the part at rest. It is possible to choose a measurement direction (or an axial direction of a laser beam from the measurement apparatus) inclined relative to the part to be tested in order to maximize the measurement accuracy of the displacements contained in the plane formed by the part at rest.

According to an embodiment in which several parts are attached to a substrate such as a wafer, it is possible to provide for sampling by detaching one or a few parts to test them individually, and to deduce therefrom a particular excitation frequency to be applied, and/or a particular measurement point to be used, and/or a particular domain of the vibration spectrum to be taken into account. In other words, this preliminary sampling allows to test single parts under good conditions (measurement errors and interference are limited) in order to choose the best test conditions for the parts remaining secured to the substrate.

### Determination of Vibration Characteristics

There are then several scenarios depending on the domain previously chosen for the excitation:
a. Frequency domain measurements
1—variant with maintained excitement:
i. Temporally integrating the oscillation amplitude and phase long enough to have good spectral resolution at the excitation frequency f₀,
ii. Shifting the oscillation frequency by delta f to excite at frequency f₀+Δf and repeating the integration step i,
iii. Reconstructing the oscillation amplitude and phase spectra as a function of the excitation frequency (possibly with multiple peaks at multiple frequencies).
2—variant with excitation whose frequency varies over time:
i. Temporally recording the oscillation amplitude and phase during the frequency sweep of the frequency range,
ii. Reiterating step i—at least once, preferably at least three times,
iii. Reconstructing the oscillation amplitude and phase spectra as a function of the excitation frequency (possibly with multiple peaks at multiple frequencies).
b. Time domain measurements:
i. Recording the temporal displacement of the coil along X, Y and Z over a sufficiently long duration to obtain a sufficiently representative signal, such as a few seconds.
ii. It is possible to choose to record the signal to make it a reference signal to be compared with other signals measured on other parts. It is also possible to choose to do a Fourier transform type signal processing to identify resonance frequencies in the recorded signal.

As a result, at least one resonance peak can be identified for each excited resonator, and it is proposed to determine the resonance frequency not on the basis of the top of the resonance peak, that is to say on the maximum amplitude, but rather on an area of the curve located between 25% and 75% of the maximum amplitude value of the resonance peak, for example from its width at mid-height. Indeed, this processing method which focuses on a portion of the curve between 25% and 75% of the maximum amplitude value of the resonance peak allows to limit the errors due to the singularity of the maximum amplitude point and to the approximation calculations to reconstruct the top portion of the resonance peak. The area of the curve located between 25% and 75% of the maximum amplitude value of the resonance peak has a better accuracy than the portion above 75% (typically the peak), which offers a better accuracy on the exact resonance frequency determined. For example, the middle of the segment connecting the two points at mid-height of the resonance peak can be taken to determine the resonance frequency associated with the peak in question.

FIG. 7 shows an example of a vibration spectrum for a point of a hairspring blank 200 of FIG. 5 free of defects, reconstructed from the displacement amplitude measurements of the measurement point considered in response to the vibrational excitation of FIG. 6, between 10 KHz and 15 kHz. The presence of three amplitude peaks can be noted, at approximately 11 kHz, 12.3 kHz, and 13.7 kHz. Although not shown, typically between 10 and 250 amplitude peaks can be identified if the vibrational excitation sweeps a range of frequency comprised between 0 Hz and 300 kHz. Each amplitude peak has a resonance frequency, and the maximum amplitudes vary greatly.

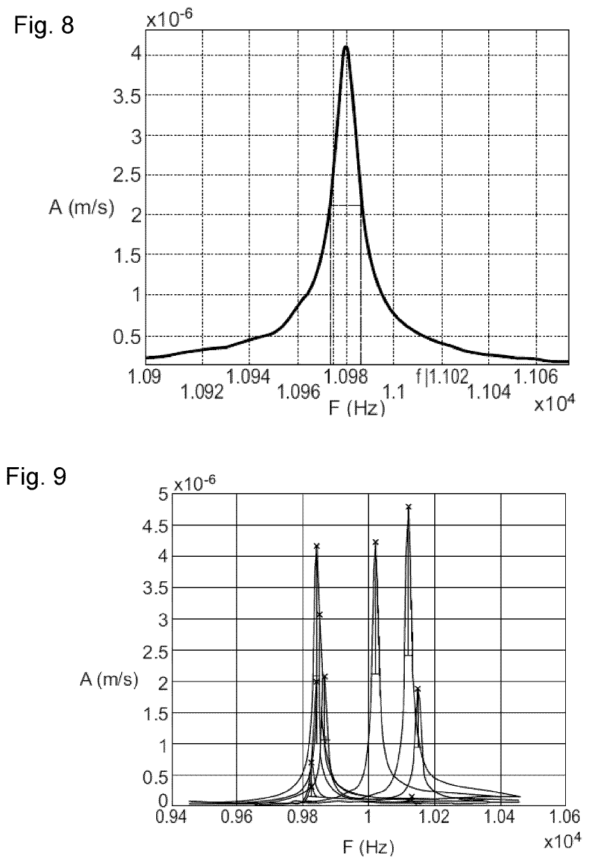

FIG. 8 shows in detail the processing that can be done on an amplitude peak for a part free of defects, that at 11 kHz for example. The aim is to find the resonance frequency and to give it a value as precise as possible. Instead of basing this processing on the maximum value of the peak, the applicant has noticed that better precision could be achieved by determining the length of the segment connecting the rising portion and the falling portion of the curve, at mid-height of the peak. The resonance frequency is typically the value in the middle of this segment. However, an interpolation can be carried out on points in the vicinity of the resonance peak to improve the precision, and to shift the chosen point on the segment, which will not be the middle, in particular if the real position of the resonance peak is shifted for example because of the chosen sampling frequency.

FIG. 9 shows, for the example of an amplitude peak at approximately 10 KHz, the amplitude peaks constructed for about ten tested hairspring blanks 200. It can be noted that from one hairspring blank to another, the frequency position of the amplitude peak varies (from approximately 9.8 kHz to 10.02 kHz), and that the maximum displacement amplitude varies in a ratio of approximately 1 to 5. Since the peaks of the amplitude peaks are not really symmetrical, it may be judicious to determine the resonance frequency on the basis of the width of the peak at mid-height. The width of the peak at mid-height can also be used to determine damping, and compare this damping to a reference value.

For these tests in FIG. 9, the following resonance frequencies could be deduced:

| Hairspring No | Resonance frequency (Hz) |
|---|---|
| 2 | 9824 |
| 9 | 9824 |
| 3 | 9840 |
| 8 | 9840 |
| 7 | 9848 |
| 4 | 9863 |
| 10 | 10020 |
| 5 | 10121 |
| 1 | 10129 |
| 6 | 10148 |

With reference to the manufacturing method described in FIGS. 3A-3F, a first optional measurement may be performed on the parts described in FIG. 3E to estimate the stiffness of the non-oxidized parts, in order to determine whether or not a dimensional correction is required. It could also be considered to perform the first optional measurement after an oxidation step adding a predetermined thickness of oxide, from which any dimensional corrections are performed. Once the parts have been oxidized (that is to say with a thermo-compensation processing), the invention proposes to perform a second measurement to determine a thermal coefficient of the Young's modulus (CTE) of the hairspring and/or a thermal coefficient (CT) of a horological system comprising the hairspring.

Accordingly, the steps implemented to determine the stiffness of the parts will be described first.

Determination of the Stiffness and/or Actual Dimensions of the Bar of the Resonators Tested

To establish a prediction model that can receive as input the vibration characteristics (typically a resonance frequency) and give as output a stiffness and/or a dimensional correction, it is necessary, during the learning phase, to provide the data relating to the stiffness and/or the dimensions of the actual bar of the resonators tested. To this end, it is possible to plan to concretely measure a natural frequency of a hairspring-balance wheel system in an environment similar to that of a particular watch mechanism.

Two alternatives can be implemented. According to a first alternative, a predetermined balance wheel can be coupled directly to the resonator still attached to the wafer, and a natural oscillation frequency of the resonator-balance wheel pair can be measured to compare this natural frequency with an expected natural frequency and, above all, to calculate the actual stiffness or the actual dimensions based on equations 1 to 3 above. According to a second alternative, the tested resonators can be finished manufacturing, in order to mount them or couple them with a balance wheel individually to again measure a natural oscillation frequency of the resonator-balance wheel pair.

In both of the above alternatives, one can go through an intermediate step of determining the stiffness of each resonator, and then determine the actual dimensions of the bar of the resonators tested. In other words, it is possible to determine the natural frequency or a resonance frequency and then the stiffness or dimensions of the resonator bar by analyzing the free oscillations of a hairspring coupled to a reference balance wheel. In this approach, a laser pointed at the balance wheel arms or the hairspring holder records the passage times of the balance wheel arms or a polarizer. An estimate of the period, then the frequency and finally the stiffness are then deduced. The data collected are essentially point clouds of the passage times.

Indeed, to evaluate the stiffness of a hairspring on the wafer, several solutions are offered, as described in particular by M. Vermot et al, in the Traité de construction horlogère (2011) on pages 178-179. For example, a dynamic evaluation can be carried out by coupling the hairspring to a reference balance wheel whose inertia is known. Measuring the frequency of the assembly allows the stiffness of the hairspring to be deduced precisely. This evaluation can be carried out on the wafer or by detaching the hairspring from the wafer. The references and prior art given above provide details on this method.

Similarly, the stiffness can also be deduced from a measurement of the reaction torque at the collet using a rheometer. The acquired signal represents the evolution of the torque as a function of the amplitude. The analysis of the slope of this curve for low amplitudes (linear portion) allows the stiffness to be deduced, and then the dimensions of the resonator bar. The dimensions of the hairspring bar can then be determined.

On the other hand, it is possible to estimate by simulation a natural frequency and/or a resonance frequency and/or the stiffness for each resonator tested on the wafer. For this purpose, dimensional measurements of each resonator tested can be carried out to reconstruct by numerical modeling the resonator in order to simulate by numerical calculation its vibration response to the imposed spectrum, and to find moreover the stiffness of the resonator.

A high-resolution 3D X-ray tomography approach would allow the extraction of point clouds giving the 3D material density of the hairsprings, and, by means of an adapted reconstruction of the images, a mapping of the hairspring section. These different types of data allow to deduce the dimensions of the bar and to estimate the stiffness of the hairspring by a geometric approach.

Another approach is to analyze the forced oscillations of a hairspring on a reference balance wheel with an escapement. A laser measurement of the passage times of the balance wheel arms (point clouds), as presented above, allows to measure the frequency and deduce the stiffness. An alternative can be considered from an acoustic acquisition (Witschi type microphone) which records the shocks of the different operating phases of the escapement/lever system. The measured data are either point clouds of the times of passage of the balance wheel arms, or the temporal evolution of the acoustic pressure level. These types of experimental data allow to deduce the period, then the frequency, then the stiffness and finally the dimensions of the resonator bar.

Returning to the tests discussed above in FIG. 9, a measurement of the stiffness was carried out by coupling each hairspring blank 200 to a reference balance wheel, and the following stiffnesses could be deduced:

| Hairspring No | Measured stiffness (10⁻⁷ N · mm) |
|---|---|
| 2 | 3.89 |
| 9 | 3.88 |
| 3 | 3.92 |
| 8 | 3.90 |
| 7 | 3.91 |
| 4 | 3.95 |
| 10 | 4.111 |
| 5 | 4.135 |
| 1 | 4.119 |
| 6 | 4.196 |

### Establishing the Prediction Model

In order to be able to predict stiffness, it is first necessary to establish or construct reference data, such as a reference spectrum. During the training phase, oscillation amplitude measurements are carried out on physical resonators, and resonance frequencies are identified. In order to subsequently be able to relate the resonance frequencies measured on resonators to stiffnesses and/or dimensional (thickness) corrections to be made, a correlation phase must be planned during which a predictive model is constructed.

The operations described above (vibration measurements, identification of resonance peaks, mid-height bandwidth and its midpoint or corrected value, determination of the stiffness and/or dimensions of the bar) allow to feed a database that can relate the position of the hairspring on the wafer, spectra or oscillation periods or mid-height bandwidth and its midpoint or corrected value with the effective stiffnesses and/or dimensions of the hairspring bar. As seen above, this database can be built from numerical simulations on a finite element model of the hairspring. These simulations allow to generate reference spectra or oscillation periods associated with stiffnesses. This database can also be supplemented by experimental measurements by measuring vibration spectra, oscillation periods and the positions of hairsprings on the wafer as well as their associated stiffnesses. One advantage of this approach is that the training database is enriched as the tests progress. This can allow to have an adaptive model according to the wafers and the hairsprings and contributes to the reduction of the standard deviation in stiffness on the wafers.

This database can be used to build a prediction model, and several solutions are offered.

A numerical model, for example polynomial, can be constructed to calculate, as a function of a resonance frequency value, a real thickness, a dimensional correction or a real stiffness.

Categorization can also be performed by performing a k-means partitioning of the input data (the results of vibration measurements, typically the frequency of the resonance peaks) and the output data (the stiffness, and/or the dimensions of the resonator bar) and relating them together to establish a correspondence.

It is also possible to plan to process the images of the resonance peaks by a neural network, for example a perceptron, to perform a classification according to stiffnesses or dimensions of the bar, the classes being able to be defined by value increments.

In summary, the learning phase comprises a test phase (excitation of resonators with measurement of the vibration characteristics to reconstruct a vibration spectrum and identify resonance frequencies). A measurement phase of the stiffnesses and/or dimensions of the resonator bar is also performed. Once the input data (the resonance frequencies) and the output data (the stiffnesses and/or dimensions of the bar) for a significant sample are available, the prediction model construction phase can be performed.

To return to the example discussed and described in relation to FIG. 9, the data collected are as follows:

| | Resonance | Measured |
|---|---|---|
| | frequency | stiffness |
| Hairspring No | (Hz) | (10⁻⁷ N · mm) |
| 2 | 9824 | 3.89 |
| 9 | 9824 | 3.88 |
| 3 | 9840 | 3.92 |
| 8 | 9840 | 3.90 |
| 7 | 9848 | 3.91 |
| 4 | 9863 | 3.95 |
| 10 | 10020 | 4.111 |
| 5 | 10121 | 4.135 |
| 1 | 10129 | 4.119 |
| 6 | 10148 | 4.196 |

Linear regression modeling was performed on the above data for the first six rows, and the following relationship could be established:

$$R = 0.0015 F - 10.894 ,$$

With
R for stiffness in 10⁻⁷ N·mm
F for the resonance frequency in Hz.

The stiffness can therefore be predicted and compared with the actual measured stiffness as shown in the table below, with the first six rows being the data used to build or train the linear regression, and the last four rows being a prediction only:

| | | Measured | Predicted | |
|---|---|---|---|---|
| | F | R (10⁻⁷ | R (10⁻⁷ | |
| No | (Hz) | N · mm) | N · mm) | Gap |
| 2 | 9824 | 3.89 | 3.84 | −1.20% |
| 9 | 9824 | 3.88 | 3.84 | −1.10% |
| 3 | 9840 | 3.92 | 3.87 | −1.40% |
| 8 | 9840 | 3.9 | 3.87 | −0.90% |
| 7 | 9848 | 3.91 | 3.88 | −0.70% |
| 4 | 9863 | 3.95 | 3.9 | −1.20% |

Test

| | | | | |
|---|---|---|---|---|
| 10 | 10020 | 4.111 | 4.136 | 0.60% |
| 5 | 10121 | 4.135 | 4.288 | 3.70% |
| 1 | 10129 | 4.119 | 4.3 | 4.40% |
| 6 | 10148 | 4.196 | 4.328 | 3.20% |

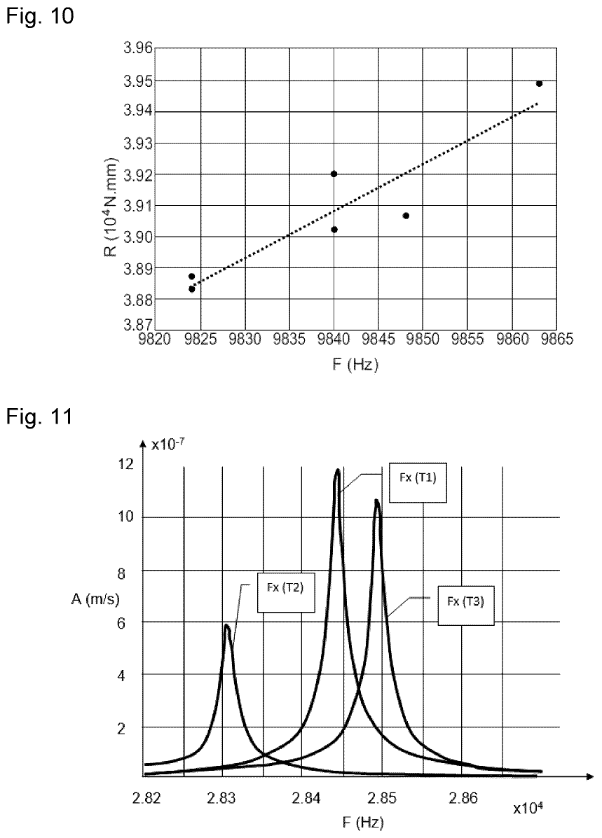

A maximum error of 4.40% could be measured, and FIG. 10 shows the linear regression line for the values of the first six lines.

It may be noted that it is advantageous to verify that the established prediction model has good sensitivity, that is to say that for two different input values, the model gives two distinct output values. The applicant has noticed that the sensitivity of the prediction model is not the same for all resonance peaks. In particular, if reference is made to the established prediction formula shown in FIG. 10, the leading coefficient is 0.0015 10⁻⁷ N·mm/Hz. On the one hand, the applicant has noticed that the leading coefficient could be larger for high resonance frequencies, which provides better prediction sensitivity, for predicting distinct stiffness or dimensional correction values, even from close resonance frequency values. It is advantageous to provide, during the learning phase, a step of comparison of the sensitivity of the prediction to verify/confirm that it is preferable to consider and choose certain resonance peaks at high frequencies (for example beyond 5 kHz) to then predict as accurately as possible a stiffness and/or a dimensional correction according to the measured vibration response.

On the other hand, the applicant also noticed that even for close resonance frequencies, the resonance modes (in particular the deformation and/or displacement modes of the resonators) could differ significantly, which can also affect the sensitivity of the stiffness and/or dimensional correction prediction. It is advantageous to provide, during the learning phase, a step of comparing the sensitivity of the prediction in order to choose to subsequently consider this or that resonance frequency and not another in order to predict as accurately as possible a stiffness and/or a dimensional correction as a function of the vibration response.

From the above remarks relating to the study of the sensitivity of the prediction, it is possible to provide, during the learning phase, to classify the different resonance peaks identified according to the sensitivity of the prediction of the stiffness and/or the dimensional correction. It is then possible to provide to define the excitation frequency range (which will be applied during a pure prediction phase) to include at least one or more resonance peaks or frequencies which give(s) the best sensitivity. Thus, imposing a variable vibrational excitation on the frequency range thus predetermined will guarantee to be able to make an accurate prediction for the identified resonance peak or predictions for each of the identified resonance peaks, which overlap or reinforce each other.

In general, the learning phase allows to choose either resonance peaks at high frequencies and/or resonance peaks which correspond to particular resonance modes allowing to predict precise and reliable values, and the frequency range will be predetermined to include at least one resonance peak and preferably several, in order to be able to make either a single prediction as precise as possible, or several predictions (one per resonance peak deemed interesting) in order to then carry out cross-checks, averages or else adjustments of the predicted values.

For example, it is possible to predict several values of stiffness or dimensional corrections from several peaks or resonance frequencies, and then calculate a definitive value, by carrying out, from the predicted values, a weighted average by assigning weights to each predicted value, each weight being determined according to the sensitivity identified for each corresponding peak or resonance frequency.

Alternatively and preferably, it is possible to provide for having only one model which takes all the peaks or resonance frequencies as input and which returns the stiffness or the dimensional correction, the learning phase of the model being used precisely to calculate the weightings on the peaks or input resonance frequencies.

### Prediction Phase

Once the learning phase is complete, it is possible to proceed to a prediction phase, for example during a resonator control method. The control method can typically be performed on hairspring blanks made on a wafer and still attached to this wafer, so as to estimate the stiffness and/or the dimensions of the bar of the hairsprings of the sample, in order to determine whether a dimensional correction is necessary.

Once the model is trained, the control procedure to be deployed can be as follows:
1) Locating the position of the hairspring on the wafer, vibration measurement of the spectra or oscillation period (as described above),
2) Predicting the stiffness and/or dimensions of the hairspring bar by application of the predictive model,
3) Determining if dimensional correction is necessary to achieve the target natural frequency or stiffness.

During the control method, it is also possible to quantify the exact correction to be made, so that the manufacturing method can include, in addition to the above control:
1) Knowing the effective stiffness of the hairspring estimated according to the model and the target stiffness and/or the target bar dimensions: applying the necessary correction dose.

Reiterating step 1) and step 2) of the control method to control the spring stiffness/dimensions and confirm that the target values are met, within a tolerance threshold, or repeating these steps and the dimensional correction until the spring stiffness/dimensions predicted by the model reach the target values.

### Sampling

It is known that several hundred hairsprings are produced on a wafer and that the dimensions of the bar of the hairsprings produced can vary according to the regions of the wafer. If the stiffness evaluation can be carried out on a single hairspring, in practice, it will be carried out on a sample of hairsprings, distributed on the wafer.

From the evaluations carried out, corrections can be made for the entire wafer in a homogeneous manner, or differentiated by region, if the results obtained vary from one hairspring to another. It is thus possible to reduce the standard deviation of the dispersion of the stiffnesses. Furthermore, if the stiffnesses of all the hairsprings are known by application of the model, it is possible to determine the optimal correction allowing to reduce the overall dispersion.

It is even possible to consider going as far as an evaluation of all the hairsprings on the wafer, in particular with a vibration evaluation, because this is very quick to carry out and can allow automation of the method.

Although the above examples have been given mainly on the basis of manufacturing hairsprings having initial bar dimensions larger than the target bar dimensions, it is also possible to provide hairsprings having initial bar dimensions smaller than the target bar dimensions. The correction step then consists of adding material, as for example described in the aforementioned document EP3181939.

The method, consisting of identifying resonance frequencies by imposing a vibrational excitation on the hairspring blanks alone, allows to quickly obtain measurement data, without having, for example, to carry out balance wheel assembly operations, while limiting measurement errors because only the hairspring blank is tested (there is no error that could be related to the balance wheel, such as its mass, assembly position, etc.).

Prediction of the Thermal Coefficient of the Young's Modulus (CTE) of the Hairspring and/or the Thermal Coefficient (CT) of a Horological System Comprising the Hairspring

For the section relating to the prediction of the thermal coefficient of the Young's modulus (CTE) of the hairspring and/or the thermal coefficient (CT) of a horological system comprising the hairspring, the following procedure can be used:
Step 1: measurements or calculations of the natural or resonance frequencies on a wafer at several temperatures T (for example 8° C., 23° C. and 38° C.);
Step 2: detach the hairsprings, assemble them with a balance wheel and mount them in movements;
Step 3: measure the thermal coefficients (CT) in movement according to the procedure of the Swiss Official Chronometer Testing Institute (COSC) for example (24 hours at 8° C., 24 hours at 23° C. and 24 hours at 38° C.);
Step 4: build a prediction model between the natural or resonance frequencies measured in step 1 and the thermal coefficients (CT) of the movement measured in step 4.

In step 1, it may be difficult to make the vibration measurement for several temperatures. It is possible to consider making the vibration measurement for a single temperature (for example 23° C., clean room temperature) then building a numerical model capable of estimating the evolution of the natural frequencies with the temperature according to the following procedure:
Building a finite element model of a hairspring with a silicon oxide layer;
Assigning the relevant material parameters and their evolutions with the temperature;
Making a modal analysis on the temperature interval [8° C. 38° C.];
Plotting the evolution of the natural or resonance frequencies as a function of the temperature and for different thicknesses of the oxide layer.

With these evolution laws, it becomes possible to predict the desired natural frequencies from a single experimental vibration measurement carried out at 23° C. However, different heating systems in an oven or by conduction could be imagined to identify these laws experimentally.

The result of such a prediction can be observed in FIG. 11, where the resonance frequencies of the same resonance mode (number x among, for example, 240 identified resonance modes) are plotted for three distinct temperatures T1, T2, T3. A difference in the value of the resonance peak frequency can be observed between the three temperatures.

Moreover, the applicant noticed that the resonance frequency was significantly affected by different oxidation values (involving variations in the thermal coefficient of the Young's modulus (CTE) of the hairspring and therefore variations in the thermal coefficient (CT) of a horological system comprising the hairspring) for certain resonance modes only.

In detail, a sensitivity analysis of the resonance frequency to the oxidation value was performed for about 240 resonance modes identified with the equation below:

$$S = \frac{Var [ E [ Y \vert Xi ] ]}{Var [ Y ]} \qquad [ equation 6 ]$$

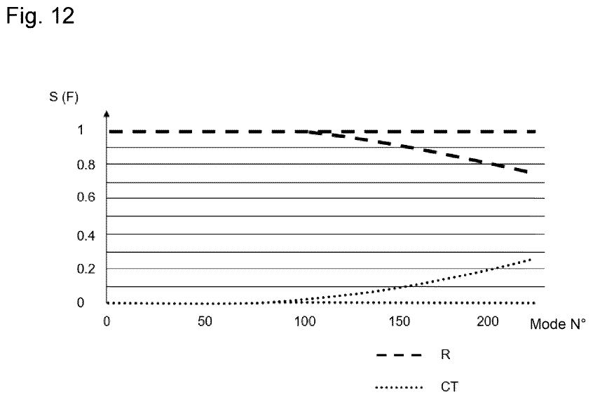

FIG. 12 shows that the sensitivity of the resonance frequency to the oxide layer thickness for predicting the Thermal coefficient of the Young's modulus (CTE) of the hairspring and/or the thermal coefficient (CT) of a horological system comprising the hairspring (curve CT) increases for some resonance modes starting from approximately the 100th identified resonance mode. It can be concluded that it is advantageous to take into account the resonance modes that have high resonance frequencies for predicting the Thermal coefficient of the Young's modulus (CTE) of the hairspring and/or the thermal coefficient (CT) of a horological system comprising the hairspring. On the other hand, the same FIG. 12 shows that the sensitivity of the resonance frequency to the oxide layer thickness and/or to the ratio of the thickness of the silicon core vs. the thickness of the silicon oxide, for predicting the stiffness (curve R) decreases for some resonance modes starting from approximately the 100th identified resonance mode. It can be concluded that it is advantageous to consider resonance modes that have low resonance frequencies to predict the hairspring stiffness.

Moreover, the applicant has noticed that for resonance modes having a high frequency, the sensitivity of the resonance frequency is particularly high for the resonance modes called “out-of-plane” resonance modes, whereas the resonance modes called “plane” resonance modes do not have any particular sensitivity. It can be concluded that it is advantageous to take into account the “out-of-plane” resonance modes which have high resonance frequencies in order to predict the thermal coefficient of the Young's modulus (CTE) of the hairspring and/or the thermal coefficient (CT) of a horological system comprising the hairspring. Conversely, it is advantageous to consider the “plane” resonance modes in order to predict the stiffness of the parts.

Step 3 can be carried out by detaching the parts measured in step 1 and mounting them in a reference movement, and the rate of these movements can be measured according to the three temperatures 8° C., 23° C., 38° C.

To establish a thermal coefficient prediction model that can receive as input the vibration characteristics and output the thermal coefficient of the Young's modulus (CTE) of the hairspring and/or the thermal coefficient (CT) of a horological system comprising the hairspring, therefore use can be made of the resonance frequency data identified at the three temperatures for the parts taken into account, and the operating data at the three temperatures for these same parts.

Once the thermal coefficient prediction model is established, a thermal coefficient prediction machine can use it to predict, from for example the resonance frequency data for an out-of-plane resonance mode having a high resonance frequency, the thermal coefficient of the Young's modulus (CTE) of the hairspring and/or the thermal coefficient (CT) of a horological system comprising the hairspring. Of course, when it comes to predicting the thermal coefficient (CT) of a horological system comprising the hairspring, the thermal coefficient prediction machine can receive as input the reference of the watch device in question, or its value or contribution to the thermal coefficient. It can indeed be considered that for a given caliber reference, the different parameters which intervene in the CT of the movement (sensitivity to the temperature of the balance wheel, the gear train, the bearings, the lubricants, etc.) are constant and do not constitute adjustment variables.

There is no longer any need to assemble movements to measure the thermal coefficient (CT) of a horological system comprising the hairspring, this time-consuming and variable step can be eliminated.

There would be the possibility of performing an iterative processing on parts of the same wafer: after predicting the thermal coefficient of the Young's modulus (CTE) of the hairspring and/or the thermal coefficient (CT) of a horological system comprising the hairspring, it would be possible to detach only the parts having the desired performances, and apply a new thermo-compensation step (oxidation and/or deoxidation) to the parts which are identified as not compatible or not conforming to the desired performances.

In summary, the invention allows to simplify the manufacturing and control methods of silicon resonators for manufacturing movements having a low or zero sensitivity to temperature variations:
by applying a particular vibrational excitation to oxidized parts,
by providing the vibration response or resonance frequencies or resonance peaks or data extracted from the vibration response to a thermal coefficient prediction machine.

With this method, it is possible to simply check whether the parts have a thermo-compensation adapted to the movement in which they will be mounted.

It can be noted that it is also possible, optionally, at a previous manufacturing step (before thermo-compensation or oxidation for example) to carry out a particular vibrational excitation and submit the vibration response or resonance frequencies or resonance peaks or data extracted from the vibration response to a stiffness prediction machine or a machine for predicting the presence of structural defects such as for example:
one or more turns glued or bridged to an adjacent turn, to the rest of the wafer, such as for example the insulating support,
a porosity, which is local or not, of the material or of the oxide,
an interface between a silicon core and an oxide layer with a void, detachment, irregularities, . . . ,
an irregular or interrupted oxide thickness . . . ,
a local defect or lack of material, such as an infiltration defect,
excess material, for example due to a masking defect,
heterogeneity of material (silicon, silicon oxide),
a defect in the flatness (smoothing) of the side rims of the bar forming the hairspring,
a defect in the verticality of the side rims of the bar forming the hairspring (a draft or an undercut of the faces), deformed, corrugated or off-center coils relative to the theoretical position . . . .

However, it can be noted that the data drawn from the vibration response and used for these stiffness or defect presence predictions are not necessarily the same as those for the thermal coefficient prediction and it can even be considered that, preferably, the data drawn from the vibration response and used are different and distinct from those for the thermal coefficient prediction.

1. A method for controlling a hairspring or a hairspring blank arranged to form a hairspring, the control method comprising the following steps:
a. applying to the hairspring or the hairspring blank a vibratory excitation varying over time to cover a predetermined frequency range,
b. identifying at least one characteristic of a resonance frequency of the hairspring or the hairspring blank, such as a resonance peak, upon or in response to vibrational excitation over the predetermined frequency range,
c. subjecting to a thermal coefficient prediction machine the resonance frequency characteristic identified in step b. to determine a thermal coefficient of the Young's modulus (CTE) of the hairspring and/or a thermal coefficient (CT) of a horological system comprising the hairspring.

2. The control method according to claim 1,
wherein step b. comprises:
b 1. a first identification step comprising identifying a first characteristic of a first resonance frequency such as a first resonance peak,
b 2. a second identification step comprising identifying a second characteristic of a second resonance frequency such as a second resonant peak, the second resonance frequency being different from the first resonance frequency,
and wherein step c. comprises:
c 1. a first prediction step consisting in subjecting to another prediction machine the first characteristic of the first resonance frequency to determine a parameter different from the thermal coefficient of the Young's modulus (CTE) of the hairspring and/or the thermal coefficient (CT) of a horological system comprising the hairspring, such as a stiffness or a defect of the hairspring or the hairspring blank,
c 2. a second prediction step consisting in subjecting to the thermal coefficient prediction machine the second characteristic of the second resonance frequency to determine the thermal coefficient of the Young's modulus (CTE) of the hairspring and/or the thermal coefficient (CT) of a horological system comprising the hairspring.

3. The control method according to claim 2,
wherein steps b1 and b2 are separated by an oxidation step,
and wherein step a. comprises:
a 1. a first step of vibrational excitation, carried out before step b1. and consisting of applying to the hairspring or the hairspring blank a first vibrational excitation that is variable over time to cover a first predetermined frequency range,
a 2. a second vibrational excitation step, carried out before step b2. and consisting of applying to the oxidized hairspring or to the oxidized hairspring blank a second vibrational excitation that is variable over time to cover the first predetermined frequency range or a second predetermined frequency range.

4. The control method according to claim 2,
wherein step a. is implemented after an oxidation step,
and wherein steps b1. and b2. take into account the same vibrational response of the hairspring or the hairspring blank.

5. The control method according to claim 2, wherein:
the first resonance frequency is chosen to be a resonance frequency of a plane resonance mode, and/or
the second resonance frequency is chosen to be a resonance frequency of an out-of-plane resonance mode.

6. The control method according to claim 2, wherein the first resonance frequency is lower than the second resonance frequency and/or:
the first resonance frequency is chosen in a range of values from 0 Hz to 100 kHz, preferably from 0 Hz to 50 kHz, more preferably from 0 Hz to 40 kHz, and very preferably from 10 kHz to 35 kHz, and/or
the second resonance frequency is chosen in a range of values from 0 Hz to 300 kHz, preferably from 50 kHz to 250 kHz, more preferably from 60 kHz to 200 kHz, and very preferably from 100 kHz to 200 KHz.

7. The control method according to claim 1, the hairspring having at least two expected predetermined resonance frequencies, wherein the frequency range is predetermined to cover at least the two expected predetermined resonance frequencies.

8. The control method according to claim 1, wherein step b is based on a measurement over time of an amplitude or a speed or an acceleration of displacement of at least one point of the hairspring or the hairspring blank, preferably carried out at least partially during step a.

9. The control method according to claim 1, the hairspring or the hairspring blank being contained in a base plane, wherein step b comprises:
a step b″ of measuring an amplitude or a speed or an acceleration of displacement of at least one point of the hairspring or the hairspring blank in a direction normal to the base plane, and/or
a step b″ of measuring an amplitude or a speed or an acceleration of displacement of at least one point of the hairspring or the hairspring blank in a direction contained in the base plane.

10. The control method according to claim 8, wherein step b. comprises:
a step of identifying a resonance peak of the hairspring or of the hairspring blank according to an amplitude or a speed of displacement of at least one point of the hairspring or of the hairspring blank.

11. The control method according to claim 10, wherein the characteristic of the resonance frequency is identified based on the width of the resonant peak, at mid-height of the maximum value of the resonant peak.

12. The control method according to claim 1, wherein the thermal coefficient prediction machine implements a regression method, for example a linear regression, to predict the thermal coefficient of the Young's modulus (CTE) of the hairspring and/or the thermal coefficient (CT) of a horological system comprising the hairspring.

13. The control method according to claim 1, comprising a preliminary step consisting in taking into account the material of the hairspring or the hairspring blank, and in adjusting a maximum amplitude of the vibrational excitation and/or a range of frequencies of the predetermined frequency range according to the material of the hairspring or the hairspring blank.

14. The control method according to claim 1, wherein, if step c. determines that the thermal coefficient of the Young's modulus (CTE) of the hairspring and/or the thermal coefficient (CT) of a horological system comprising the hairspring is outside a range of expected values, then the method comprises at least one step of identifying or isolating or reworking or scrapping the hairspring or the hairspring blank.

15. The control method according to claim 1, wherein, if step c. determines that the thermal coefficient of the Young's modulus (CTE) of the hairspring and/or the thermal coefficient (CT) of a horological system comprising the hairspring is outside a range of expected values, then the method comprises at least one step consisting in defining a step of carrying out a treatment of the hairspring or the hairspring blank, such as a thermo-compensation, oxidation or deoxidation step, to set the thermal coefficient of the Young's modulus (CTE) of the hairspring and/or the thermal coefficient (CT) of a horological system comprising the hairspring within the range of expected values.

16. A prediction machine learning method to implement step c. of the control method of claim 1, comprising the steps of:
i—forming hairsprings or hairspring blanks and applying a thermo-compensation step thereto,
ii—applying to each of the hairsprings or each of the hairspring blanks a vibrational excitation that is variable over time to cover a predetermined frequency range, iii—identifying at least one characteristic of a resonance frequency of each hairspring or each hairspring blank when applying the predetermined frequency range and recording the temperature of the parts during step ii- and/or iii-,
iv′—mounting a plurality of hairsprings or hairspring blanks in an oscillating mechanism having a predetermined inertia so as to measure for each hairspring or hairspring blank a sustained oscillation frequency or a rate of the horological system formed by, or comprising, the oscillating mechanism at least at one predetermined temperature and preferably at least at two predetermined temperatures,
and/or
iv″—modeling in a simulation tool a plurality of hairsprings or hairspring blanks in an oscillating mechanism having a predetermined inertia so as to calculate for each hairspring or hairspring blank a sustained oscillation frequency and/or a thermal coefficient of a horological system comprising the hairspring and/or the rate of the horological system comprising the hairspring at least at one predetermined temperature and preferably at least at two predetermined temperatures,
v—optionally, deducing at least one expected resonance frequency from the resonance frequency identified in step iii-, and/or from the sustained oscillation frequency and/or from the rate of the horological system measured in step iv′- and/or calculated in step iv-
vi—deducing a thermal coefficient of the Young's modulus (CTE) of the hairspring and/or the thermal coefficient (CT) of a horological system comprising the hairspring from the measurements of step iv′- and/or the calculations of step iv″-
vii—providing to the prediction machine, and for each hairspring or hairspring blank:
the characteristic of the resonance frequency identified in step iii-;
optionally, the same characteristic of the expected resonance frequency;
the temperature recorded during step ii- and/or iii-;
the thermal coefficient of the Young's modulus (CTE) of the hairspring and/or the thermal coefficient (CT) of a horological system comprising the hairspring deduced in step vi-.
